(19) United States
(12) Patent Application Publication
(10) Pub. No.: US 2016/0133271 A1
(43) Pub. Date: May 12, 2016

(54) Microphone With Electronic Noise Filter

(71) Applicant: Knowles Electronic, LLC, Itasca, IL (US)

(72) Inventor: Michael Kuntzman, Chicago, IL (US)

(21) Appl. No.: 14/926,703

(22) Filed: Oct. 29, 2015

Related U.S. Application Data
(60) Provisional application No. 62/078,131, filed on Nov. 11, 2014.

(51) Int. Cl. G10L 21/0232; H03F 3/183; H04R 3/06; H04R 19/00; H04R 19/04

(52) U.S. Cl. CPC G10L 21/0232; H04R 19/005; H04R 19/04; H04R 3/06; H03F 3/183; H03F 2200/03; H03F 2200/165; H03F 2200/372

(57) ABSTRACT

An acoustic apparatus includes a microelectromechanical system (MEMS) device, a controlled filter coupled to the MEMS device, and an amplifier. The controllable filter and the amplifier are coupled together at a node. A cut-off frequency of the filter is selectable based upon reception or non-reception of a low frequency audio signal by the acoustic apparatus.

### CROSS-REFERENCE TO RELATED APPLICATION

This patent claims benefit under 35 U.S.C. §119(e) to U.S. Provisional Application No. 62078131 entitled “Microphone with electronic noise filter” filed Nov. 11, 2014, the content of which is incorporated herein by reference in its entirety.

### TECHNICAL FIELD

This application relates to microphones and mitigating or eliminating noise concerns associated with these devices.

### BACKGROUND OF THE INVENTION

Microphones are used to obtain sound energy and convert the sound energy into electrical signals. Once obtained, the electrical signals can be processed in a number of different ways.

One example of a microphone is a Micro-Electro-Mechanical System (MEMS) microphone. MEMS microphones are typically composed of two main components: a MEMS device (including a diaphragm and a back plate) that receives and converts sound energy into an electrical signal, and an Application Specific Integrated Circuit (ASIC) (or other circuits such as buffers, amplifiers, and analog-to-digital converters). The ASIC receives the electrical signal from the MEMS device and performs post-processing on the signal and/or buffering the signal for the following circuit stages in a larger electronic environment.

Microphones also operate in a wide variety of different environments. Some environments can be quiet, while others have considerable noise. Environmental noise (not originating in the microphone) can come in many forms but one of the most common forms is from wind noise. If nothing is done to negate the noise, the received signal will potentially not be heard or recognized by a listener.

Previous filters were always activated and were always applied to all signals resulting in poor low frequency responses and, in some cases, higher self-noise of the microphone. In another approach, larger pierce sizes were used in the diaphragms in the MEMS devices to alleviate noise issues, but this resulted in poor low frequency response and higher noise in the audio band. One approach has used an acoustic vent which may be opened and closed. This is undesirable because of the complexity the mechanical valve introduces to the MEMS design and reliability issues it may introduce.

The drawbacks of previous approaches have resulted in some general user dissatisfaction.

### BRIEF DESCRIPTION OF THE DRAWINGS

For a more complete understanding of the disclosure, reference should be made to the following detailed description and accompanying drawings wherein:

FIG. 1 comprises a block diagram of a high pass filter circuit used with a microphone according to various embodiments of the present invention;

FIG. 2 comprises a block diagram of another high pass filter circuit used with a microphone according to various embodiments of the present invention;

FIG. 3 comprises a block diagram of still another high pass filter circuit used with a microphone according to various embodiments of the present invention;

FIG. 4 comprises a block diagram of yet another high pass filter circuit used with a microphone according to various embodiments of the present invention;

FIG. 5 comprises a graph showing some of the advantages of using the high pass filter circuits described herein according to various embodiments of the present invention.

Skilled artisans will appreciate that elements in the figures are illustrated for simplicity and clarity. It will further be appreciated that certain actions and/or steps may be described or depicted in a particular order of occurrence while those skilled in the art will understand that such specificity with respect to sequence is not actually required. It will also be understood that the terms and expressions used herein have the ordinary meaning as is accorded to such terms and expressions with respect to their corresponding respective areas of inquiry and study except where specific meanings have otherwise been set forth herein.

### DETAILED DESCRIPTION

The present approaches provide a switchable passive filter that is utilized before amplification of a received signal occurs. By “passive,” it is meant non-active components such as resistors and capacitors are utilized. In other embodiments, active components may be used. For example, a switchable active filter at the input of the microphone is provided. In one aspect, a micro-electro-mechanical System (MEMS) device receives a signal from a microphone. A switchable high pass filter (for example) is selectively utilized to act on the signal (or not act on the signal) before the signal is sent to an amplifier for further processing. The filter is only engaged in the circuit when wind noise (or other types of noise) is present. In one approach, a DSP may receive readings from an external wind velocity sensor or other wind sensing (or measuring) device. A signal is transmitted from the DSP to the switch that will either include or exclude the filter from the circuit based upon whether a predetermined amount of noise is measured or sensed. Other approaches include human input from the user engaging the filter and DSP analyzing the output of the microphone for the acoustic signature of wind noise.

In many of these embodiments, an acoustic apparatus includes a microelectromechanical system (MEMS) device, a controlled filter coupled to the MEMS device, and an amplifier. The controllable filter and the amplifier are coupled together at a node. A cut-off frequency of the filter is selectable based upon reception or non-reception of a low frequency audio signal by the acoustic apparatus.

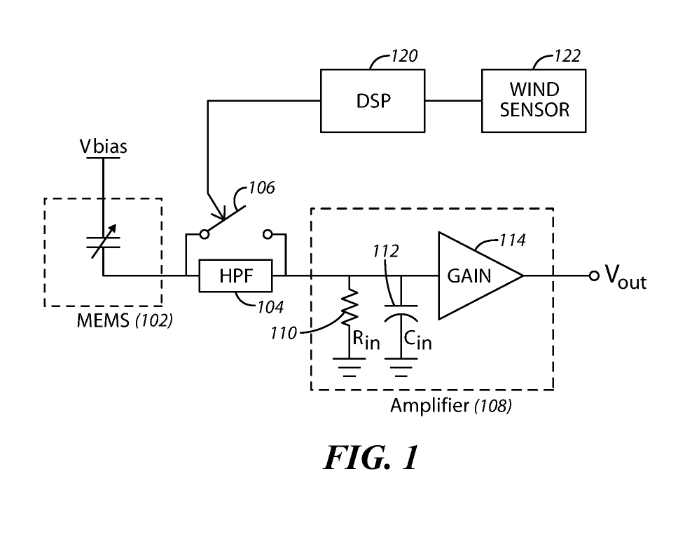

Referring now to FIG. 1, one example of a circuit that uses a selectively included passive filter is described. A MEMS device 102 couples to a high pass filter 104. Inclusion of the high pass filter 104 in the circuit is controlled by a switch 106. The output of the high pass filter 104 (when included in the circuit) couples to an amplifier 108. The amplifier 108 includes a gain stage, which may be greater than, equal to, or less than unity and which has a finite input resistance 110 and capacitance 112.

The MEMS device 102 is a capacitance which varies in response to sound pressure. These approaches sometimes include a diaphragm and a back plate. In other examples, sensors that do not use diaphragms and back plates may be used. For example, some sensors (e.g., piezoelectric sensors) may have a capacitance which varies with sound pressure. Sound energy is received at the MEMS device 102 and moves the diaphragm. Movement of the diaphragm creates an electrical signal, which is selectively processed by the high pass filter 104 (or bypasses the high pass filter 104).

The high pass filter 104 receives the signal from the MEMS device 102 when the switch 106 is open. When the switch 106 is closed, the signal is not received by the high pass filter 106, but passes unimpeded to the amplifier 108. The high pass filter 104 may be constructed of one or more resistors and capacitors (in one example) that passes signals above a predetermined cutoff frequency and filters out signals below this predetermined cutoff frequency. The capacitance of the MEMS device may be used as part of the filter.

As mentioned, the amplifier 108 includes an input resistance 110 and capacitance 112, and a gain stage 114. These elements provide amplification and/or buffering to the signal received from the high pass filter 108 (or the signal that bypasses the high pass filter 108).

The switch 106 may couple to a digital signal processor (DSP) 120 or some other type of processing device. The DSP (or other processing device) 120 controls the operation of the switch 106. In these regards, the DSP (or other processing device) 120 may couple to a wind speed sensor 122. When wind of a certain amount or speed is detected (or wind of sufficient strength is otherwise detected), the DSP 120 may send a signal to open the switch 106 thereby allowing the signal detected by the MEMS device 102 to be filtered by the high pass filter 104. Alternatively and when wind of a certain amount or speed is not detected, the DSP 120 may send a signal to close the switch 106 thereby allowing the signal created by the MEMS device 102 to bypass the high pass filter 104. Generally speaking, the DSP 120 and wind sensor 122 may be replaced by anything which decides when to engage the filter. In another example, a DSP may be used to look at microphone output for a characteristic wind noise signature. In another example, an action from the user may be used to engage the filter when they are in a windy environment. These comments apply to all of the examples in all the figures discussed herein.

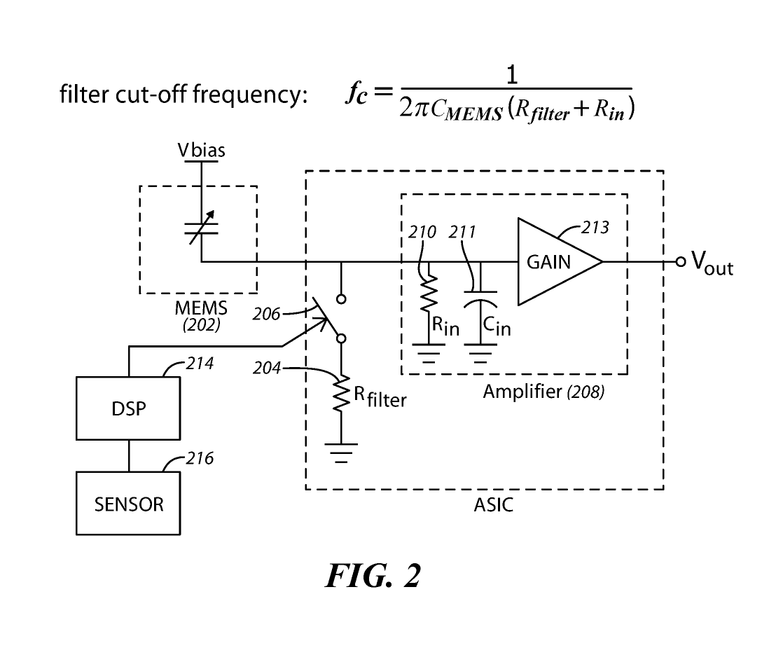

Referring now to FIG. 2, another example of a circuit that uses a selectively included passive filter is described. A MEMS device 202 couples to an ASIC 203. The ASIC 203 includes a high pass filter which is included or excluded from the circuit by a switch 206. The high pass filter includes a resistor 204 (having a value of R_{filter}) and utilizes a capacitance of the MEMS device 202 (C_{MEMS}). An amplifier 208 includes a resistance 210, a capacitance 211, and a gain stage 213.

The MEMS device 202 often includes a diaphragm and a back plate. Sound energy is received at the MEMS device 202 and moves the diaphragm. Movement of the diaphragm creates an electrical signal, which is selectively processed by or bypasses the high pass filter. The invention may also be applied to other types of MEMS microphones, such as piezoelectric and piezoresistive, which may not include a back plate.

The signal from the MEMS device 202 is high pass filtered when the switch 206 is closed. When the switch 206 is open, the signal from the MEMS device 202 is not filtered by the high pass filter, but passes unimpeded to the amplifier 208. The cutoff frequency of the filter (f_{c}) is 1/(2*pi*C_{MEMS}*(R_{filter}+Rᵢₙ)). It will be understood that the resistor 204 could be external to the ASIC 203. The resistance may be implemented using a diode or transistor in some cases.

As mentioned, the amplifier 208 includes a gain or buffer stage 213 which has an input resistance 210 and capacitance 211. These elements provide amplification to the signal received from the high pass filter (or the signal that bypasses the high pass filter).

The switch 206 may couple to a digital signal processor (DSP) 214 or some other type of processing device. The DSP (or other processing device) 214 controls the operation of the switch 206. In these regards, the DSP (or other processing device) 214 may couple to a wind speed sensor 216. When wind of a certain amount or speed is detected (or wind of sufficient strength is otherwise detected), the DSP 214 may send a signal to close the switch 206 thereby allowing the signal detected by the MEMS device 202 to be filtered by the high pass filter. Alternatively and when wind of a certain amount or speed is not detected, the DSP 214 may send a signal to open the switch 206 thereby allowing the signal created by the MEMS device 202 to bypass the high pass filter.

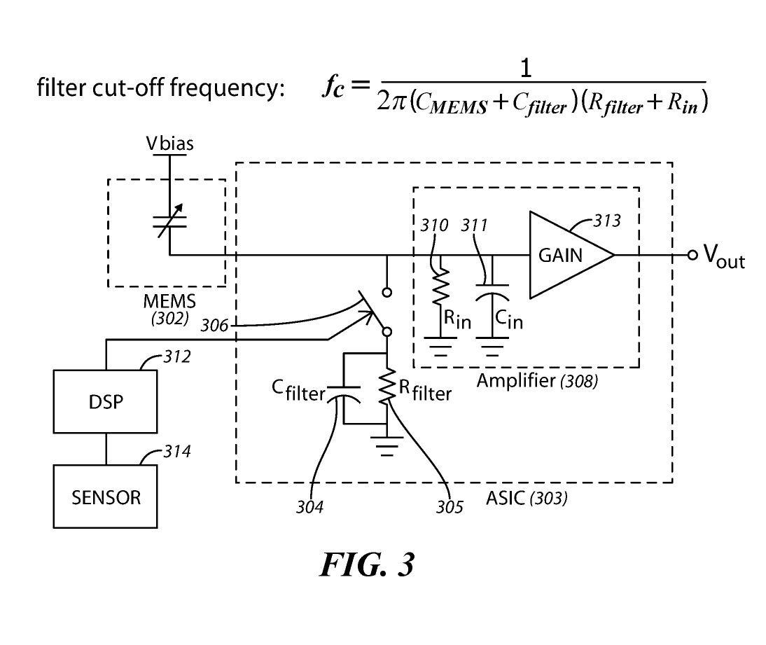

Referring now to FIG. 3, another example of a circuit that uses a selectively included passive filter is described. A MEMS device 302 couples to an ASIC 303. The ASIC 303 includes a high pass filter (including resistor 304 (having a value of R_{filter}) and a capacitor 305) which is controlled by a switch 306. The high pass filter also utilizes the capacitance of the MEMS device 302 (C_{MEMS}). An amplifier 308 includes a gain or buffer stage which has a finite input impedance, represented by a resistor 310, a capacitor 311, and an operational amplifier 313.

The MEMS device 302 includes a diaphragm and a back plate. Sound energy is received at the MEMS device 302 and moves the diaphragm. Movement of the diaphragm creates an electrical signal, which is selectively processed by or bypasses the high pass filter.

The high pass filter receives the signal from the MEMS device 302 when the switch 306 is open. When the switch 306 is open, the signal from the MEMS device 302 is not filtered by the high pass filter, but passes unimpeded to the amplifier 308. The cutoff frequency of the filter (f_{c}) is 1/(2*pi*(C_{MEMS}+C_{filter})*(R_{filter}+Rᵢₙ)). The resistor 304 could be external to the ASIC. This configuration may help prevent wind noise from saturating the amplifier.

As mentioned, the amplifier 308 includes a gain or buffer stage which has a finite input impedance, represented by a resistor 310, a capacitor 312, and an operational amplifier 314. These elements provide amplification to the signal received from the high pass filter (or the signal that bypasses the high pass filter).

The switch 306 may couple to a digital signal processor (DSP) 314 or some other type of processing device. The DSP (or other processing device) 314 controls the operation of the switch 306. In these regards, the DSP (or other processing device) 314 may couple to a wind speed sensor 316. When wind of a certain amount or speed is detected (or wind of sufficient strength is otherwise detected), the DSP 314 may send a signal to close the switch 306 thereby allowing the signal created by the MEMS device 302 to be filtered by the high pass filter. Alternatively and when wind of a certain amount or speed is not detected, the DSP 314 may send a signal to open the switch 306 thereby allowing the signal detected by the MEMS device 302 to bypass the high pass filter.

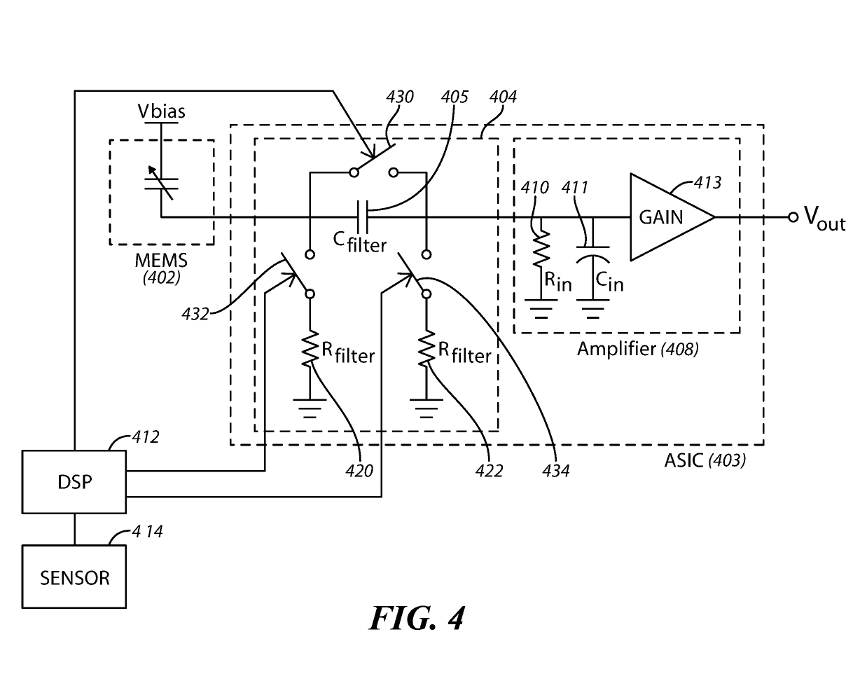

Referring now to FIG. 4, still another example of a circuit that uses a selectively included passive filter is described. A MEMS device 402 is coupled to an ASIC 403. The ASIC 403 also includes a high pass filter 404 (including resistor 420 (having a value of R_{filter}), resistor 422 (having a value of R_{filter}) and a capacitor 405 (with capacitance C_{filter}). The inclusion of the filter 404 in the circuit is controlled by a first switch 430, a second switch 432, and a third switch 434. In one aspect, all three switches would be actuated by a single control. Or along the same lines, the three switches could be combined as part of a multiple-pole multiple throw switch. The high pass filter 404 also utilizes a capacitance of the MEMS device 402 (C_{MEMS}). An amplifier includes a gain or buffer stage which has a finite input impedance, represented by 408 a resistor 410, a capacitor 411, and an operational amplifier 413.

The MEMS device 402 includes a diaphragm and a back plate. Sound energy is received at the MEMS device 402 and moves the diaphragm. Movement of the diaphragm creates an electrical signal, which is selectively processed by or bypasses the high pass filter 404.

The amplifier 408 receives the signal from the MEMS device 402 when the switch 430 is closed. When the switch 430 is open, and one or both of the switches 432 and 434 are closed, the signal from the MEMS device 302 is filtered by the high pass filter 406. The resistors 420 and 422 could be external to the ASIC.

As mentioned, the amplifier 408 includes a gain or buffer stage which has a finite input impedance, represented by a resistor 410, a capacitor 411, and an operational amplifier 413. These elements provide amplification to the signal received from the high pass filter (or the signal that bypasses the high pass filter).

The switches 430, 432, and 434 may couple to a digital signal processor (DSP) 414 or some other type of processing device. The DSP (or other processing device) 414 controls the operation of the switches 430, 432 and 434. In these regards, the DSP (or other processing device) 414 may couple to a wind speed sensor 416. When wind of a certain amount or speed is detected (or wind of sufficient strength is otherwise detected), the DSP 414 may send a signal to open the switch 430 and close one or both of the switches 432 and 434 thereby allowing the signal created by the MEMS device 402 to be filtered by the high pass filter. Alternatively and when wind of a certain amount or speed is not detected, the DSP 414 may send a signal to close the switch 430 thereby allowing the signal detected by the MEMS device 402 to bypass the high pass filter.

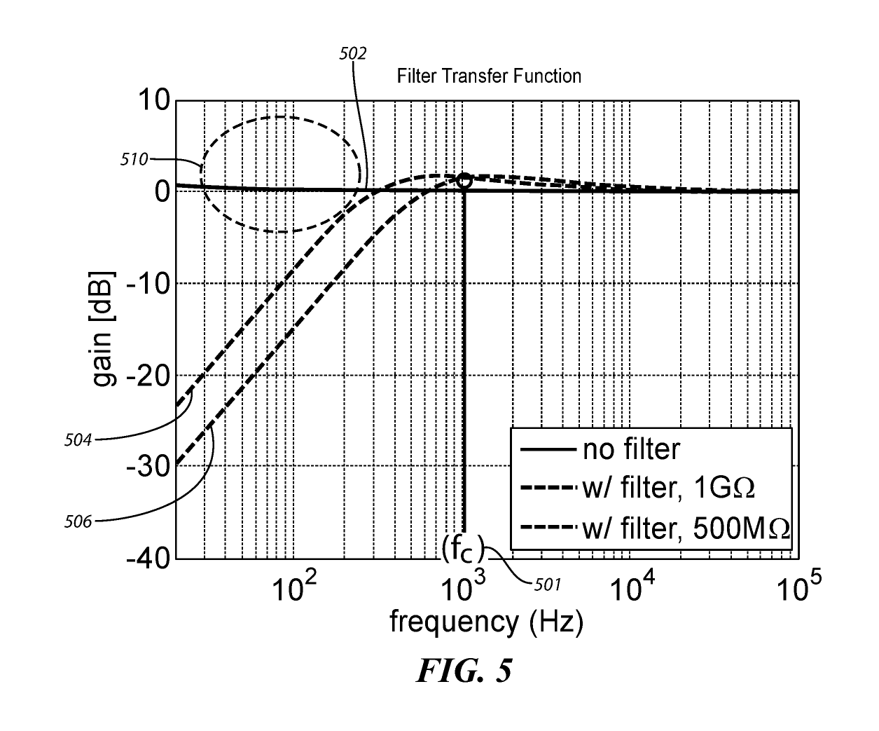

Referring now to FIG. 5, examples of some of the advantages of the present approaches are described. The y-axis shows microphone gain, while the x-axis shows frequency. A cut-off frequency (f_{c}) 501 is used when the filter is used. A first curve 502 shows a response when no filter is used, that is, when there is no wind. A curve 504 shows a second response with a filter and a first gain, and another curve 506 shows a response when a filter is used with a different gain.

In region 510 any speech being filtered would be buried in wind noise. Consequently, any speech in that range would have been lost regardless of whether a filter were used. Because the filter can be switched off when not needed, a more aggressive approach can be taken with the cutoff frequency resulting in improved wind-noise rejection.

Preferred embodiments of this invention are described herein, including the best mode known to the inventors for carrying out the invention. It should be understood that the illustrated embodiments are exemplary only, and should not be taken as limiting the scope of the invention.

What is claimed is:

1. An acoustic apparatus, comprising:
a microelectromechanical system (MEMS) device;
a controlled filter coupled to the MEMS device;
an amplifier;
wherein the controllable filter and the amplifier are coupled together at a node;
wherein a cut-off frequency of the filter is selectable based upon reception or non-reception of a low frequency audio signal by the acoustic apparatus.

2. The acoustic apparatus of claim 1, wherein the low frequency audio signal has a frequency of less than 1000 HZ.

3. The acoustic apparatus of claim 1, wherein the controllable filter comprises a high pass filter.

4. The acoustic apparatus of claim 1, wherein the controllable filter is controlled by a switch, the switch selectively activating the controllable filter.

5. The acoustic apparatus of claim 4, wherein the switch is controlled by a processor.

6. The acoustic apparatus of claim 5, wherein the processor is coupled to a sensor, and wherein the sensor selectively receives the low frequency audio signal.

7. The acoustic apparatus of claim 6, wherein the low frequency audio signal is wind.

8. The acoustic apparatus of claim 1, wherein the controllable filter comprising at least one resistor and at least one capacitor.
